(19) United States
(12) Patent Application Publication
(10) Pub. No.: US 2009/0183902 A1
(43) Pub. Date: Jul. 23, 2009

(54) MULTILAYER FILM FOR WIRING AND WIRING CIRCUIT

(76) Inventors: Takashi Kubota, Saitama (JP); Yoshinori Matsuura, Saitama (JP)

Correspondence Address: ROBERTS & ROBERTS, LLP;ATTORNEYS AT LAW, P.O. BOX 484, PRINCETON, NJ, 08542-0484, US

(21) Appl. No.: 12/374,859

(22) PCT Filed: Oct. 11, 2007
(86) PCT No.: PCT/JP2007/069826

§ 371 Date: Jan. 23, 2009

(30) Foreign Application Priority Data
Oct. 16, 2006 (JP) 2006-282050

(51) Int. Cl. H05K 1/09; H01B 5/00; B44C 1/22

(52) U.S. Cl. 174/257; 174/126.2; 216/13

(57) ABSTRACT

The provided is a technology for forming a circuit for wiring, which can show a lower resistance, and particularly proposes a laminated film for wiring, which can surely decrease wiring resistance even in a large-sized liquid crystal display.

The laminated film for wiring according to the present invention is characterized in that the laminated film for wiring comprises a metal layer with low resistance and an Al—Ni-based alloy layer containing 0.5 at % to 10.0 at % Ni laminated thereon. The metal layer with low resistance contains at least one or more elements among Au, Ag, Cu and Al, and has a specific resistance of 3 μΩ·cm or less.

### TECHNICAL FIELD

The present invention relates to a technology for forming a wiring circuit of an element in a display device such as a liquid crystal display, and particularly relates to a laminated film for wiring, which is suitable for realizing a wiring circuit of low resistance.

### BACKGROUND ART

In recent years, a liquid crystal display is used for displays in various electronic equipments, and particularly a demand for a liquid crystal television is remarkably expanding, and a further large-sized liquid crystal display is being developed progressively. A thin film transistor (hereinafter abbreviated as TFT), for instance, is known as the display device of the liquid crystal display, and an aluminum (Al)-based alloy is used as a wiring circuit material constituting the TFT.

In the case of an active-matrix type of a liquid crystal display, for instance, the element of a TFT working as a switching element is constituted by: a transparent electrode (hereinafter occasionally referred to as transparent electrode layer) such as ITO (Indium Tin Oxide) and IZO (Indium Zinc Oxide); and a wiring circuit (hereinafter occasionally referred to as wiring circuit layer) formed from a metal material with low resistance such as Al and Cu. In such an element structure, there exist a portion in which the wiring circuit is bonded to the transparent electrode and a portion in which the wiring circuit is bonded to n⁺-Si (phosphorous-doped semiconductor layer) in the TFT, so that a layer made from a high melting metal material such as molybdenum (Mo), tungsten (W) and titanium (Ti) is formed therein, which is so-called a cap layer.

This cap layer functions as a protection layer for a wiring circuit made from a low-resistance material such as Al and Cu. The cap layer also has a function for preventing the metal material with low resistance such as Al from mutually diffusing with Si due to a heating process when the wiring circuit is bonded to the semiconductor layer such as n⁺-Si, in the manufacturing process. The cap layer is also placed in between the transparent electrode layer and the metal material with low resistance so as to realize an ohmic junction, when the transparent electrode layer is bonded to the metal material with low resistance such as Al.

Here, one example of the above described element structure is specifically described below with reference to FIG. 1. FIG. 1 illustrates a schematic sectional view of an a-Si type of a TFT in a liquid crystal display. This TFT structure includes an electrode wiring circuit layer 2 made from an Al-based alloy wiring material constituting a gate electrode part G and a cap layer 3 made from Mo, Mo—W or the like formed on a glass substrate 1. This gate electrode part G has a gate insulation film 4 for protection made from SiNx provided thereon. This gate insulation film 4 has an a-Si semiconductor layer 5, a channel protection film layer 6, an n⁺-Si semiconductor layer 7, a cap layer 3, an electrode wiring circuit layer 2 and a cap layer 3 sequentially deposited thereon, which are appropriately patterned to form a drain electrode part D and a source electrode part S on the gate insulation film 4. The drain electrode part D and the source electrode part S are coated with a resin for flattening the surface of the element or an insulation film 4′ made from SiNx. Furthermore, a contact hole CH is provided on the insulation film 4′ in a source electrode part S side, and a transparent electrode layer 7′ made from ITO or IZO is formed thereon. When the Al-based alloy wiring material is used in such an electrode wiring circuit layer 2, the structure makes the cap layer 3 exist in between the n⁺-Si semiconductor layer 7 and the electrode wiring circuit layer 2, or in between the transparent electrode layer 7′ in the contact hole CH and the electrode wiring circuit layer 2 (see Non-Patent Document 1, for instance).

Non-Patent Document 1: “Next-Generation Liquid Crystal Display Technology” written and edited by Tatsuo Uchida, first edition, p. 36-38, published by Kogyo Chosakai Publishing, Inc., Nov. 1, 1994

### DISCLOSURE OF THE INVENTION

### Problems to be Solved by the Invention

The element structure as shown in FIG. 1 includes a cap layer made from Mo, W or the like, which shows a comparatively large resistance, so that a wiring resistance of the composed element naturally tends to increase though a metal material with low resistance such as Al and Cu is adopted therein. When the sixth to seventh generation liquid crystal television and the eighth generation or later large-sized liquid crystal television are manufactured, in particular, the length of a wiring circuit is extended due to the tendency of increasing the size, and the wiring resistance of the element is anticipated to further increase. For this reason, a new cap layer has been demanded which shows lower resistance than that of a high melting metal material such as Mo and W which is conventionally used as the cap layer, can prevent the mutual diffusion between a metal material with low resistance forming the wiring circuit and Si, or can be directly bonded to a transparent electrode layer.

The present invention is designed with respect to the above circumstances, and provides a technology for forming a circuit for wiring, which can show a lower resistance, and is particularly directed at proposing a laminated film for wiring, which can surely decrease wiring resistance even in a large-sized liquid crystal display.

### Means for Solving the Problems

In order to solve the above described problems, the present invention relates to a laminated film for wiring characterized in that the laminated film for wiring comprises a metal layer with low resistance and an Al—Ni-based alloy layer containing 0.5 at % to 10.0 at % Ni laminated thereon.

The metal layer with low resistance according to the present invention preferably contains at least one or more elements among Au, Ag, Cu and Al.

The metal layer with low resistance according to the present invention preferably has a specific resistance of 3 μΩ·cm or less.

The present invention relates to a wiring circuit which can be obtained by etching the above described laminated film for wiring according to the present invention. Furthermore, the present invention relates to an element having the wiring circuit. In addition, the element according to the present invention may have a structure in which one part of the Al—Ni-based alloy layer is directly bonded to a transparent electrode layer and/or a semiconductor layer.

### BRIEF DESCRIPTION OF THE DRAWINGS

FIG. 1 is a schematic sectional view of a TFT; and

FIG. 2 is a schematic plan view of an evaluation sample.

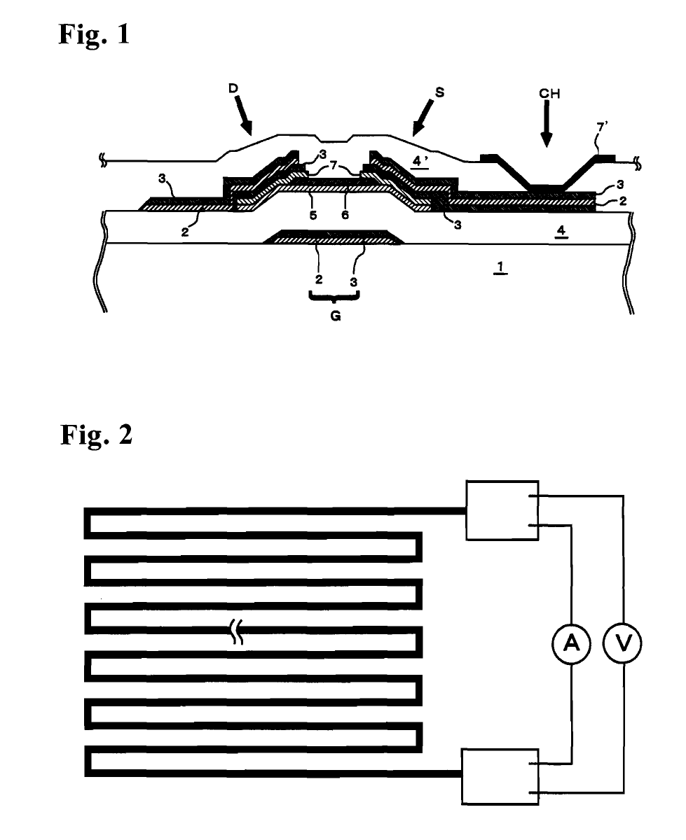

### BEST MODE FOR CARRYING OUT THE INVENTION

Preferred embodiments according to the present invention is described below, but the present invention is not limited to the following embodiments.

A laminated film for wiring according to the present invention is a laminate of a metal layer with low resistance and an Al—Ni-based alloy layer. This Al—Ni-based alloy has superior heat resistance against a heat history, and has characteristics of hardly forming a defect such as a protrusion and a recess, which is formed on the surface of the film due to stress distortion when the Al—Ni-based alloy is heat-treated, and is referred to as so-called a hillock or a dimple. The Al—Ni-based alloy can be directly bonded to a transparent electrode layer such as ITO, or can be directly bonded to a semiconductor layer such as n⁺-Si. Furthermore, the Al—Ni-based alloy shows a considerably lower resistance than that of a high melting metal material such as Mo, W and Ti, which has been used for a conventional cap layer, though showing a slightly higher resistance than that of pure Al. Moreover, the Al—Ni-based alloy has more superior chemical resistance characteristics than those of pure Al, pure Cu and pure Ag, and accordingly can perform a function as the cap layer. For this reason, the Al—Ni-based alloy layer can decrease wiring resistance, by being used for the cap layer in place of the high melting metal material such as Mo and W, which has been used for a conventional cap layer.

The Al—Ni-based alloy specifically includes an Al—Ni alloy, an Al—Ni—B (boron) alloy, an Al—Ni—C (carbon) alloy, an Al—Ni—Nd (neodymium) alloy and an Al—Ni—La (lanthanum) alloy. The Al—Ni-based alloy preferably contains 0.5 at % to 10.0 at % Ni. When Nd and La are used, the Al—Ni-based alloy preferably contains 0.5 at % to 2.0 at % Ni. The Al—Ni-based alloy preferably contains 0.1 at % to 1.0 at % B, C, Nd and La. These Al—Ni-based alloys can easily control the specific resistance of the Al—Ni-based alloy layer itself to 10 μΩ·cm or less, can easily realize direct bonding which develops adequate device characteristics, and accordingly can decrease wiring resistance when a wiring circuit is formed of the laminated film for wiring, which has the metal layer with low resistance laminated on these Al—Ni-based alloy layers, and when various elements such as the TFT are structured.

Furthermore, among these Al—Ni-based alloys, an Al—Ni—B alloy which contains 0.1 at % to 0.8 at % B (boron) is more preferable. The Al—Ni—B alloy having such a composition can be directly bonded to the transparent electrode layer such as ITO and IZO and can be directly bonded also to a semiconductor layer such as n⁺-Si, shows a low bond resistance when the Al—Ni—B alloy has been directly bonded to the transparent electrode layer or the semiconductor layer, and can form an element which also has superior heat resistance. In adopting this Al—Ni—B alloy, it is preferable if the Al—Ni—B alloy contains 3.0 at % or more Ni, and 0.80 at % or less B. The Al—Ni—B alloy more preferably contains 3.0 at % to 6.0 at % Ni, and 0.20 at % to 0.80 at % B. This is because the Al—Ni—B alloy having such a composition has superior heat resistance property against each heat history in a process of manufacturing the element. In addition, the Al-based alloy according to the present invention preferably contains 75 at % or more Al itself in order to acquire low resistance characteristics.

In a laminated film for wiring according to the present invention, a metal layer with low resistance to be laminated with the Al—Ni-based alloy metal preferably contains at least one or more elements of Au, Ag, Cu and Al. Such a metal layer with low resistance preferably shows a specific resistance of 3 μΩ·cm or less. The metal layer with low resistance according to the present invention is not particularly limited, as long as the layer is made from a metal material such as pure Al, pure Cu, pure Ag, pure Au and an alloy containing these elements, or a metal material that shows the specific resistance of 3 μΩ·cm or less, which are conventionally used as a wiring circuit material. When pure Al is used for the metal layer with low resistance, the laminated film for wiring according to the present invention can be collectively etched with the same etchant, which can simplify a process of forming the wiring circuit. Accordingly, pure Al is preferably used for the metal layer with low resistance, from the view point of achieving both of the decrease of wiring resistance and the simplification of the process of forming the wiring circuit.

A laminated film for wiring according to the present invention can be formed with a sputtering technique, a CVD technique, a printing technique or the like. Among the techniques, a preferred technique is the sputtering technique. When the sputtering technique is employed, the film can be formed on conditions that the substrate overheat temperature is room temperature (30° C.) to 200° C., the DC is 3 to 30 W/cm², the pressure is 0.25 to 0.6 Pa and the film thickness is 500 to 5000 Å. The order of lamination is not particularly limited. An Al—Ni-based alloy layer may be laminated on a metal layer with low resistance, and on the contrary, the metal layer with low resistance may be laminated on the Al—Ni-based alloy layer. The order of lamination can be determined so as to match an element structure and a wiring circuit structure to be applied. When the metal layer with low resistance and the Al—Ni-based alloy layer according to the present invention are formed, an unavoidable contaminant such as a sputtering gas component which is mixed during film formation is allowed to exist, as long as the layers show the effect according to the present invention.

When the laminated film for wiring according to the present invention is formed with the sputtering technique, a sputtering target to be used for the metal layer with low resistance can be prepared by mixing each metal of Au, Ag, Cu Al and the like, melting and casting the metal. Similarly, an Al—Ni-based alloy target to be used can be prepared by mixing aluminium with Ni or further with each metal of the third additional element, melting and casting the mixture. The sputtering target obtained with a powder molding process, a spray forming process or the like also can be used. The metal layer with low resistance and the Al—Ni-based alloy layer can be formed to easily acquire the same composition as that of the target, though the composition may be slightly affected by film-forming conditions in sputtering.

A laminated film for wiring according to the present invention can be formed into a wiring circuit with a general photolithographic technique. In this photolithographic process, a resist which is used in the manufacturing process of an element such as a TFT can be used, and the well-known application conditions can be also employed. Specifically, a resist containing a novolac resin is used, and can be formed into a resist film with a thickness of 1.0 to 1.5 μm by operating a spin coater at 3,000 rpm. In the photolithographic process, a well-known technique can be employed also for the pre-baking treatment of the resist. The resist can be pre-baked, for instance, on conditions of using a hot plate and heating the resist to a temperature of 100 to 120° C. for 30 seconds to 5 minutes.

To exposure treatment in the photolithographic process, a general exposure condition can be applied which is known in a process of manufacturing an element such as a TFT. Specifically, a UV-exposure quantity can be set, for instance, at 15 to 100 mJ/cm² by a total light exposure quantity. A Cr photomask can be used as a mask for use in forming a circuit pattern.

For development in the photolithographic process, such a general developer can be used as to match a resist type. The developer preferably includes sodium dihydrogen phosphate, m-sodium silicate or TMAH (tetramethylarnmonium hydroxide), for instance. The particularly preferred developer is the TMAH. When TMAH is used, the developer can contain 2.0 to 3.0 wt % TMAH by concentration. The developer is kept at a liquid temperature of preferably 20 to 40° C., because the liquid temperature largely affects patterning properties of the resist.

An etching process following development can be conducted with any technique of wet etching and dry etching. For instance, when the wet etching technique is employed, the pattern can be formed by using an etchant which fits the composition of an Al—Ni-based alloy layer and an etchant which fits the composition of a metal layer with low resistance. The Al—Ni-based alloy layer can be etched by using an etchant of a phosphoric-acid-based mixed acid. The metal layer with low resistance containing Au as a main component can be etched by using each etchant of a cyan-base, a nitrohydrochloric-acid-base or an iodine-base. The metal layer with low resistance containing Ag as a main component can be etched by using an etchant of a sulfuric-acid-base or a nitric-acid-base. The metal layer with low resistance containing Cu as a main component can be etched by using an acidic etchant of a ferric chloride solution or a cupric chloride solution, an alkaline etchant containing an inorganic ammonium salt or the like, or an etchant of a sulfuric acid-hydrogen peroxide mixture. The metal layer with low resistance containing Al as a main component can be etched by using an etchant of a phosphoric-acid-based mixed acid. However, when the metal layer with low resistance contains Al as a main component, the Al—Ni-based alloy layer and the metal layer with low resistance can be etched at the same time by using the etchant of the phosphoric-acid-based mixed acid. In the above description, the etching treatment conditions may be appropriately determined while considering the type of the etchant and the composition of the laminated film for wiring.

In stripping treatment for the resist after the layers have been etched, the resist-stripping liquid to be used is not particularly limited. Any one of a water-based stripping liquid and a non-water-based stripping liquid can be used. The water-based stripping liquid is a solution containing water, and occasionally contains organic amines and a glycol in the water. The non-water-based stripping liquid is a solution which does not contain water but contains a polar solvent such as dimethylsulfoxide and acetone, and/or organic amines such as an alkanolamine and 2-aminoethanol. A more preferred stripping liquid is the water-based stripping liquid. A further preferred stripping liquid is the water-based stripping liquid containing glycol and the organic amines, and the most preferred stripping liquid is the water-based stripping liquid containing the organic amines. The resist can be stripped on conditions of a liquid temperature of 40 to 80° C. and a stripping period of time of 1 minute to 10 minutes. A DIP (dipping) method and a shower method can be employed as the method of stripping treatment, but a preferred method is the shower method.

A general cleaning condition which is known in a process of manufacturing an element such as a TFT can be applied in cleaning treatment after the resist has been stripped. Specifically, alcohol cleaning treatment or ultrapure water cleaning treatment can be applied, for instance. The cleaning method includes a DIP (dipping) method and a shower method, but the shower method is preferable.

A laminated film for wiring according to the present invention can be applied to various applications including a switching element in a TFT, a TFD (MIM) and the like, an LED, an LCD panel, a touch panel, an electrode wiring in an organic or inorganic EL panel, and extraction wiring.

The laminated film for wiring according to the present invention is described below while taking the case of using pure Al for a metal layer with low resistance and using an Mo film as a cap layer, and the case of using pure Al for the metal layer with low resistance and using an Al—Ni-based alloy film as the cap layer, as examples. When Mo is used for the cap layer and pure Al is used for the metal layer with low resistance (Al/Mo structure), the metal layer with low resistance needs to be coated with an Mo cap layer having the thickness of 500 Å on a side to be covered with an insulation film, in order to prevent a defect such as a hillock from being formed in the pure Al when a substrate is heated to a temperature of 300° C. to 350° C. when the film of SiNx to be a gate insulation film is formed. In such a case, a gate wiring resistance for the wiring length of 100 inch becomes 3.02×10⁴Ω at a theoretical value. However, this Al/Mo structure may cause a side hillock therein, and is not considered to be sufficiently reliable. For this reason, the Al—Ni-based alloy (for instance, Al—3.0 at % Ni—0.4 at % B alloy) which has the same thickness as that of the Mo film is used as the cap layer. Then, the gate wiring resistance becomes 2.89×10⁴Ω. Thus, the Al—Ni-based alloy can reduce the wiring resistance by 4%. When the Al—Ni-based alloy is laminated on pure Al in the metal layer with low resistance, the laminate inhibits a side hillock from being formed, because the Al—Ni-based alloy has an almost equal coefficient of thermal expansion to that of pure AL, and is more preferable than the laminate using Mo for the cap layer.

### EXAMPLES

In these examples, the result of having investigated the wiring resistances of gate wiring circuits of 60-inch panels is described below, which were formed by using Cr for a cap layer and by using an Al-3.0 at % Ni-0.4 at % B alloy for the cap layer. Pure Al (4N), pure Cu (4N) and pure Ag (4N) were used for a metal layer with low resistance.

The gate wiring circuit having a trilayer structure was formed by the steps of forming the cap layer on a glass substrate, forming the metal layer with low resistance thereon and forming the cap layer on the metal layer with low resistance, and had lines formed into the width of 10 μm. The gate wiring with the wire length of 132.5 cm was prepared while assuming that the gate wiring is used in a 60-inch panel, and the wiring resistance was measured and evaluated. The evaluation sample was prepared in the following way.

At first, an evaluation sample having employed Cr for the cap layer is described below. A Cr film (with specific resistance of 12 μΩcm) of the cap layer was formed into predetermined thicknesses (300 Å, 500 Å and 1,000 Å) on the glass substrate, by using a magnetron-sputtering apparatus and a target of a Cr alloy on conditions of the power source to be charged of 3.0 Watt/cm², the argon gas flow rate of 100 ccm and the pressure of 0.5 Pa. Subsequently, a metal layer with low resistance (of pure Al, pure Cu and pure Ag) was formed into predetermined thicknesses (2,000 Å and 3,000 Å) on the cap layer. This metal layer with low resistance was formed by using the magnetron-sputtering apparatus and a target for a metal layer with low resistance (of pure Al, pure Cu and pure Ag) on conditions of the power source to be charged of 3.0 Watt/cm², the argon gas flow rate of 100 ccm, and the pressure of 0.5 Pa. Furthermore, the Cr film of the cap layer was formed on the metal layer with low resistance into the same thicknesses (300 Å, 500 Å and 1,000 Å) as those of the cap layer which had been firstly formed, by using the target of the Cr alloy on the above described sputtering conditions. In addition, each thickness of the formed films was controlled by adjusting a sputtering period of time.

Next, the trilayer-laminate was coated with a resist (TFR-970: made by Tokyo Ohka Kogyo Co., Ltd./application condition: spin coater at 3,000 rpm while targeting resist thickness of 1 μm after resist has been baked), and was pre-baked (at 110° C. for 1.5 minutes).

Then, a pattern film for forming a circuit with the width of 10 μm was placed on the laminate having the resist thereon, and the resist was exposed to light (with mask aligner MA-20: made by MIKASA CO.,LTD./ on exposure condition of 15 mJ/cm²). Subsequently, the resist was developed with the use of an alkali developer containing tetramethylammonium hydroxide (hereinafter abbreviated as TMAH developer) in the concentration of 2.38%, at the liquid temperature of 23° C. After having been developed, the resultant laminate was post-baked with the use of a hot plate (100° C. and 3 minutes).

Subsequently, the exposed Cr film was etched. A liquid containing 100 g/L of sodium hydroxide and 200 g/L of potassium ferricyanide was used as an etchant for Cr. The etchant was controlled to the liquid temperature of 32° C. After the top surface of the exposed Cr film had been etched, the Cr film was cleaned with the use of ultrapure water.

Subsequently, the metal layer with low resistance was etched, which had been exposed due to the removal of the Cr film on the top surface. When the metal layer with low resistance was pure Al, the layer was etched with the use of an etchant of a mixed acid for Al (volume ratio/phosphoric acid:nitric acid:acetic acid:water=16:1:2:1). When the metal layer with low resistance was pure Cu, the layer was etched with the use of a cupric chloride solution. When the metal layer with low resistance was pure Ag, the layer was etched with the use of an etchant of 0.5 M sulfuric acid solution (at room temperature).

After the metal layer with low resistance had been etched, the layer was cleaned with the use of ultrapure water. Then, the Cr film of the bottom layer was etched with the use of the above described etchant for Cr, and was cleaned with the use of ultrapure water again. Afterwards, the resist was removed with the use of a resist-stripping liquid (ST106: made by Tokyo Ohka Kogyo Co., Ltd.), and the remaining stripping liquid was removed with the use of isopropyl alcohol. Then, the sample was cleaned with water, and was dried. In this way, the evaluation samples were prepared. As is shown in Table 1, the evaluation samples were provided with gate wiring circuits having three types of cap layer/wiring layer with low resistance/cap layer, which were Cr/Al/Cr, Cr/Cu/Cr and Cr/Ag/Cr, and of which each layer had different thickness.

On the other hand, the evaluation sample which used an Al—3.0 at % Ni—0.4 at % B alloy for a cap layer was prepared in the following way. At first, an Al—Ni—B alloy film (with specific resistance of 3.8 μΩcm) of the cap layer was formed into predetermined thicknesses (300 Å, 500 Å and 1,000 Å) on a glass substrate by using a magnetron-sputtering apparatus and a target of an Al—3.0 at % Ni—0.4 at % B alloy on conditions of the power source to be charged of 3.0 Watt/cm², the Argon gas flow rate of 100 ccm and the pressure of 0.5 Pa. Subsequently, a metal layer with low resistance (of pure Al, pure Cu and pure Ag) was formed on the cap layer into a predetermined thickness (2,000 Å and 3,000 Å). The metal layer with low resistance was formed on the above described conditions. Furthermore, the Al—Ni—B alloy film of a cap layer was formed on the metal layer with low resistance into the same thicknesses (300 Å, 500 Å and 1,000 Å) as those of the cap layer which had been firstly formed, by using the target of the Al—3.0 at % Ni—0.4 at % B alloy on the above described sputtering conditions. In addition, each thickness of the formed films was controlled by adjusting a sputtering period of time.

The above samples were subjected to the steps of resist application, exposure, development, etching and resist stripping, which were conducted on the same conditions as in the preparation of the evaluation samples having the above described Cr film formed thereon as the cap layer. However, the cap layer was the Al—Ni—B alloy film, so that the cap layer was etched with the use of an etchant of a mixed acid for Al (volume ratio/phosphoric acid:nitric acid:acetic acid:water=16:1:2:1). When the metal layer with low resistance was made from pure Al, a trilayer of cap layer/metal layer with low resistance/cap layer was collectively etched. In this way, the evaluation samples were prepared. As is shown in Table 1, the evaluation samples were provided with gate wiring circuits having three types of cap layer/electric wiring layer with low resistance/cap layer, which were Al—Ni—B/Al/Al—Ni—B, Al—Ni—B/Cu/Al—Ni—B and Al—Ni—B/Ag/Al—Ni—B, and in which each layer had different thickness.

The wiring resistances of the evaluation samples which were prepared in the above way were measured. This wiring resistance was measured by the method of: preparing the evaluation samples having such a comb pattern (with wiring width of 10 μm) thereon as to have the total wire length equal to that in a 60-inch panel as is illustrated in FIG. 2, and measuring the resistance between terminals of the comb pattern. The measurement result of the wiring resistances is shown in Table 1 and Table 2.

TABLE 1

| | | Al—0.4B—3Ni | | | Cr | | |
|---|---|---|---|---|---|---|---|
| Cap layer | | (3.8 μΩcm) | | | (12 μΩcm) | | |
| Metal layer | | 300 Å/ | 500 Å/ | 1000 Å/ | 300 Å/ | 500 Å/ | 1000 Å/ |
| with low | | M/ | M/ | M/ | M/ | M/ | M/ |
| resistance | | 300 Å | 300 Å | 1000 Å | 300 Å | 300 Å | 1000 Å |
| Al | 2000 Å | 16.1 | 15.1 | 11.1 | 18.5 | 18.1 | 15.9 |
| | 3000 Å | 11.5 | 11.0 | 8.7 | 12.7 | 12.5 | 11.4 |
| Cu | 2000 Å | 11.9 | 11.4 | 9.0 | 13.2 | 13.0 | 11.8 |
| | 3000 Å | 8.4 | 8.1 | 6.8 | 9.0 | 8.9 | 8.3 |
| Ag | 2000 Å | 8.9 | 8.6 | 7.1 | 9.5 | 9.4 | 8.8 |
| | 3000 Å | 6.1 | 6.0 | 5.2 | 6.4 | 6.4 | 6.1 |

(kΩ)

TABLE 2

| | | Al—0.2B—1.5Ni | | | Al—0.4B—5.0Ni | | |
|---|---|---|---|---|---|---|---|
| Cap layer | | (3.2 μΩcm) | | | (4.2 μΩcm) | | |
| Metal layer | | 300 Å/ | 500 Å/ | 1000 Å/ | 300 Å/ | 500 Å/ | 1000 Å/ |
| with low | | M/ | M/ | M/ | M/ | M/ | M/ |
| resistance | | 300 Å | 300 Å | 1000 Å | 300 Å | 300 Å | 1000 Å |
| Al | 2000 Å | 15.8 | 14.5 | 10.1 | 16.6 | 15.6 | 11.6 |
| | 3000 Å | 11.2 | 10.5 | 8.5 | 11.9 | 11.8 | 9.0 |
| Cu | 2000 Å | 11.8 | 11.5 | 8.8 | 12.2 | 11.5 | 9.1 |
| | 3000 Å | 8.5 | 8.1 | 6.6 | 8.6 | 8.0 | 6.8 |
| Ag | 2000 Å | 8.8 | 8.7 | 7.0 | 9.1 | 8.9 | 8.0 |
| | 3000 Å | 6.3 | 6.0 | 5.4 | 6.3 | 6.2 | 5.7 |

(kΩ)

When the wiring resistances are compared between the samples having the cap layer of an Al—Ni—B alloy film and the cap layer of a Cr film respectively, based on the result shown in Table 1 and Table 2, samples which employed pure Al as a metal layer with low resistance and the Al—Ni—B alloy film as the cap layer showed the lower wiring resistance by 30% at the maximum. In addition, the sample which employed pure Cu for the metal layer with low resistance showed the lower wiring resistance by 23% at the maximum. Furthermore, the sample which employed pure Ag for the metal layer with low resistance showed the lower wiring resistance by 19% at the maximum.

In addition, the bondability between a wiring layer with low resistance provided with each cap layer and ITO to be a transparent electrode layer was examined. As a result, it was confirmed that the bondability had no practical problem. The bondability with the ITO was examined by the steps of: preparing a test sample of a kelvin element; heat-treating each test sample at 250° C. in the ambient atmosphere for 30 minutes; continuously passing an electric current (3 mA) from terminal portions of the test sample; and measuring the electric resistance. As for the resistance measurement condition at this time, the respective test samples were subjected to the ambient atmosphere at 85° C., which is so-called the life acceleration test condition (in accordance with JIS C 5003: in 1974, and Reference document (book name “Efficient Way and Actual Practice of Reliability Acceleration Tests”: written and edited by Youji Kanuma, J-TECHNO INC.)); and were subjected to the measurement of a period of time (operation time before failure) before the resistance changed into a 100 times or more larger value of the initial resistance at the starting time of the measurement, under the life acceleration test condition. The reliability for the bondability with the ITO was thus examined. The test sample which did not cause a failure even for more than 250 hours on the life acceleration test condition was determined to have the reliability of satisfying the acceptance standard. As a result, all of the wiring layers with low resistance provided with each cap layer showed the excellent reliability in direct bonding with ITO.

### INDUSTRIAL APPLICABILITY

A laminated film for wiring and a wiring circuit according to the present invention does not use a high melting metal material such as Mo and W which has been conventionally used, accordingly can decrease wiring resistance when an element including the laminated film is structured, and can surely decrease wiring resistance particularly even in a large-sized liquid crystal display. In addition, the laminated film for wiring does not use the high melting metal material such as Mo and W, which is scarce resource, and accordingly can make an element as a TFT stably supplied.

1. A laminated film for wiring which comprises a metal layer with low resistance and an Al—Ni-based alloy layer containing 0.5 at % to 10.0 at % Ni laminated thereon.

2. The laminated film for wiring according to claim 1, wherein the metal layer with low resistance contains at least one of Au, Ag, Cu, and Al.

3. The laminated film for wiring according to claim 1, wherein the metal layer with low resistance has a specific resistance of 3 μΩ-cm or less.

4. A wiring circuit obtained by etching the laminated firm for wiring according to claim 1.

5. An element having the wiring circuit according to claim 4.

6. The element according to claim 5, wherein the element has a structure in which a part of an Al—Ni-based alloy layer is directly bonded to a transparent electrode layer and/or a semiconductor layer.

7. The laminated film for wiring according to claim 1, wherein the Al—Ni-based alloy layer is formed of an Al—Ni—B alloy.

8. The laminated film for wiring according to claim 2, wherein the Al—Ni-based alloy layer is formed of an Al—Ni—B alloy.

9. The laminated film for wiring according to claim 2, wherein the metal layer with low resistance has a specific resistance of 3 μΩ-cm or less.

10. The laminated film for wiring according to claim 7, wherein the metal layer with low resistance has a specific resistance of 3 μΩ-cm or less.

11. The laminated film for wiring according to claim 8, wherein the metal layer with low resistance has a specific resistance of 3 μΩ-cm or less.

12. A wiring circuit obtained by etching the laminated film for wiring according to claim 2.

13. A wiring circuit obtained by etching the laminated film for wiring according to claim 3.

14. A wiring circuit obtained by etching the laminated film for wiring according to claim 7.

15. A wiring circuit obtained by etching the laminated film for wiring according to claim 8.

16. A wiring circuit obtained by etching the laminated film for wiring according to claim 9.

17. A wiring circuit obtained by etching the laminated film for wiring according to claim 10.

18. A wiring circuit obtained by etching the laminated film for wiring according to claim 11.

19. An element having the wiring circuit according to claim 12.

20. An element having the wiring circuit according to claim 13.
